(19) United States
(12) Patent Application Publication
(10) Pub. No.: US 2023/0421121 A1
(43) Pub. Date: Dec. 28, 2023

(54) Split Bias with Single Control Current Source for Radio Frequency Power Amplifier

(71) Applicant: Huawei Technologies Co., Ltd., Shenzhen (CN)

(72) Inventor: Jason Xiangdong Deng, Greensboro, NC (US)

(21) Appl. No.: 18/463,569

(22) Filed: Sep. 8, 2023

Related U.S. Application Data
(63) Continuation of application No. PCT/US2021/021915, filed on Mar. 11, 2021.

(51) Int. Cl. H03F 3/24; H04B 1/04; H03F 1/02

(52) U.S. Cl. CPC H03F 3/245; H04B 1/0458; H03F 1/0216; H03F 2200/451; H03F 2200/318

(57) ABSTRACT

A power amplifier includes a first driver stage, a second driver stage, and a biasing component including a first emitter follower circuit and a second emitter follower circuit. The biasing component is configured to receive a first source current from a first current source, and provide a first bias voltage to the first driver stage using the first emitter follower circuit and a second bias voltage to the second driver stage using the second emitter follower circuit. The first bias voltage and the second bias voltage are based upon the first current source.

### CROSS-REFERENCE TO RELATED APPLICATIONS

This application is a continuation of International Patent Application No. PCT/US2021/021915, filed on Mar. 11, 2021, and entitled “Split Bias with Single Control Current Source for Radio Frequency Power Amplifier,” which application is hereby incorporated herein by reference.

### TECHNICAL FIELD

The present disclosure relates generally to a system and method for digital communications, and, in particular embodiments, to a radio frequency (RF) power amplifier including split bias with a single control current source.

### BACKGROUND

In a wireless terminal, such as a user equipment (UE), a cellular phone, or other wireless communication equipment, a radio frequency (RF) power amplifier (PA) front end module is a critical component. The role of the RF PA front end module is to amplify modulated RF signals received from a transceiver baseband accurately, and send the amplified modulated RF signals to an antenna for radiating out to a base station with a desired output power, minimal battery consumption, and minimal spurious emissions.

In modern digital telecommunications, especially the latest generation of 5G technology with a new high frequency band, due to high power out requirements and potential high frequency loss, common two stage RF PA designs increasingly struggle with high gain requirements that such designs are often unable to meet. Three or more stage designs for such RF Pas are increasingly desired.

With the use of three or more stages in power amplifier design, one of the dilemmas faced by a designer to how to bias the stages with a minimal amount of current sources that are available from a current controller while still allowing the use of multiple current sources to control a configurable output stage or for other uses such as providing a thermal adjustable reference device. Therefore, there is a need for a RF PA in which the limited available external sources provided from a bias controller are able to bias multiple stages of the RF PA.

### SUMMARY

Example embodiments provide a radio frequency (RF) power amplifier (PA) including split bias with a single control current source.

In accordance with an example embodiment, a power amplifier driver is provided. The power amplifier driver includes a first driver stage, a second driver stage, and a biasing component. The biasing component includes a first emitter follower circuit and a second emitter follower circuit. The biasing component is configured to receive a first source current from a first current source, and provide a first bias voltage to the first driver stage using the first emitter follower circuit and a second bias voltage to the second driver stage using the second emitter follower circuit. The first bias voltage and the second bias voltage are based upon the first current source.

Optionally, in any of the preceding embodiments, the first driver stage includes a first power amplification device and the second driver stage includes a second power amplification device.

Optionally, in any of the preceding embodiments, the first bias voltage is provided to the first power amplification device, and the second bias voltage is provide to the second power amplification device.

Optionally, in any of the preceding embodiments, the power amplifier driver further includes a diode circuit coupled to a common node between the first emitter follower circuit and the second emitter follower circuit, the diode circuit configured to receive the first source current from the first current source.

Optionally, in any of the preceding embodiments, the first emitter follower circuit includes a first semiconductor device, and the second emitter follower circuit includes a second semiconductor device.

Optionally, in any of the preceding embodiments, a first base of the first semiconductor device is coupled to the first source current, and a second base of the second semiconductor device is coupled to the first source current.

Optionally, in any of the preceding embodiments, a first emitter of the first semiconductor device is coupled to the first driver stage, the first emitter providing the first bias voltage to the first driver stage.

Optionally, in any of the preceding embodiments, a second emitter of the second semiconductor device is coupled to the second driver stage, the second emitter providing the second bias voltage to the second driver stage.

Optionally, in any of the preceding embodiments, the first emitter is coupled to the first driver stage via a first resistive element having a first resistance value, and the second emitter is coupled to the second driver stage via a second resistive element having a second resistance value.

Optionally, in any of the preceding embodiments, a ratio of the first bias voltage to the second bias voltage is adjustable based upon a ratio of the first resistance value and the second resistance value.

Optionally, in any of the preceding embodiments, the ratio of the first bias voltage to the second bias voltage is further adjustable based upon a ratio of an emitter size of the first emitter follower circuit to an emitter size of the second emitter follower circuit.

Optionally, in any of the preceding embodiments, a first collector of the first semiconductor device is coupled to a first voltage source, and a second collector of the second semiconductor device is coupled to a second voltage source.

Optionally, in any of the preceding embodiments, a first collector of the first semiconductor and a second collector of the second semiconductor device are coupled to a same voltage source.

Optionally, in any of the preceding embodiments, a first output of the first driver stage is coupled to a first input of the second driver stage.

In accordance with an example embodiment, a power amplifier includes a first driver stage, a second driver stage coupled to the first driver stage, an output stage coupled to the second driver stage, and a biasing component. The biasing component includes a first emitter follower circuit and a second emitter follower circuit. The biasing component is configured to receive a first source current from a first current source, and provide a first bias voltage to the first driver stage using the first emitter follower circuit and a second bias voltage to the second driver stage using the second emitter follower circuit. The first bias voltage and the second bias voltage are based upon the first current source.

Optionally, in any of the preceding embodiments, the output stage is configured to receive a third bias voltage from a second current source.

Optionally, in any of the preceding embodiments, the first current source is different from the second current source.

Optionally, in any of the preceding embodiments, the first driver stage includes a first power amplification device and the second driver stage includes a second power amplification device.

Optionally, in any of the preceding embodiments, the first bias voltage is provided to the first power amplification device, and the second bias voltage is provide to the second power amplification device.

Optionally, in any of the preceding embodiments, the power amplifier further includes a diode circuit coupled to a common node between the first emitter follower circuit and the second emitter follower circuit, the diode circuit configured to receive the first source current from the first current source.

Optionally, in any of the preceding embodiments, the first emitter follower circuit includes a first semiconductor device, and the second emitter follower circuit includes a second semiconductor device.

Optionally, in any of the preceding embodiments, a first base of the first semiconductor device is coupled to the first source current, and a second base of the second semiconductor device is coupled to the first source current.

Optionally, in any of the preceding embodiments, a first emitter of the first semiconductor device is coupled to the first driver stage, the first emitter providing the first bias voltage to the first driver stage.

Optionally, in any of the preceding embodiments, a second emitter of the second semiconductor device is coupled to the second driver stage, the second emitter providing the second bias voltage to the second driver stage.

Optionally, in any of the preceding embodiments, the first emitter is coupled to the first driver stage via a first resistive element having a first resistance value, and the second emitter is coupled to the second driver stage via a second resistive element having a second resistance value.

Optionally, in any of the preceding embodiments, a ratio of the first bias voltage to the second bias voltage is adjustable based upon a ratio of the first resistance value and the second resistance value.

Optionally, in any of the preceding embodiments, the ratio of the first bias voltage to the second bias voltage is further adjustable based upon a ratio of an emitter size of the first emitter follower circuit to an emitter size of the second emitter follower circuit.

Optionally, in any of the preceding embodiments, a first collector of the first semiconductor device is coupled to a first voltage source, and a second collector of the second semiconductor device is coupled to a second voltage source.

Optionally, in any of the preceding embodiments, a first collector of the first semiconductor device and a second collector of the second semiconductor device are coupled to a same voltage source.

In accordance with an example embodiment, a device includes a transceiver, a power amplifier coupled to the transceiver, the power amplifier including a first driver stage and a second driver stage, a first current source, and a biasing component. The biasing component includes a first emitter follower circuit and a second emitter follower circuit. The biasing component is configured to receive a first source current from the first current source, and provide a first bias voltage to the first driver stage using the first emitter follower circuit and a second bias voltage to the second driver stage using the second emitter follower circuit based upon the first current source.

Optionally, in any of the preceding embodiments, the first driver stage includes a first power amplification device and the second driver stage includes a second power amplification device.

Optionally, in any of the preceding embodiments, the first bias voltage is provided to the first power amplification device, and the second bias voltage is provide to the second power amplification device.

Optionally, in any of the preceding embodiments, the device further includes a diode circuit coupled to a common node between the first emitter follower circuit and the second emitter follower circuit, the diode circuit configured to receive the first source current from the first current source.

Optionally, in any of the preceding embodiments, the first emitter follower circuit includes a first semiconductor device, and the second emitter follower circuit includes a second semiconductor device.

Optionally, in any of the preceding embodiments, a first base of the first semiconductor device is coupled to the first source current, and a second base of the second semiconductor device is coupled to the first source current.

Optionally, in any of the preceding embodiments, a first emitter of the first semiconductor device is coupled to the first driver stage, the first emitter providing the first bias voltage to the first driver stage.

Optionally, in any of the preceding embodiments, a second emitter of the second semiconductor device is coupled to the second driver stage, the second emitter providing the second bias voltage to the second driver stage.

Optionally, in any of the preceding embodiments, the first emitter is coupled to the first driver stage via a first resistive element having a first resistance value, and the second emitter is coupled to the second driver stage via a second resistive element having a second resistance value.

Optionally, in any of the preceding embodiments, a ratio of the first bias voltage to the second bias voltage is adjustable based upon a ratio of the first resistance value and the second resistance value.

Optionally, in any of the preceding embodiments, the ratio of the first bias voltage to the second bias voltage is further adjustable based upon a ratio of an emitter size of the first emitter follower circuit to an emitter size of the second emitter follower circuit.

Optionally, in any of the preceding embodiments, a first collector of the first semiconductor device is coupled to a first voltage source, and a second collector of the second semiconductor device is coupled to a second voltage source.

Optionally, in any of the preceding embodiments, a first output of the first driver stage is coupled to a first input of the second driver stage.

Optionally, in any of the preceding embodiments, the device further includes an output stage coupled to a second output of the second driver stage, the output stage configured to receive a third bias current from a second current source.

Optionally, in any of the preceding embodiments, the first current source is different from the second current source.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates an example wireless communications system that may employ aspects of the present disclosure;

FIG. 2 illustrates an example of architecture for a UE in which a biasing component may be utilized;

FIG. 3 illustrates a first example of a radio frequency (RF) power amplifier (PA) having a biasing component to bias two or more driver stages in the RF PA using a single current source;

FIG. 4 illustrates a second example of a RF PA having a biasing component to bias two or more driver stages in the RF PA using a single current source;

FIG. 5 is an example graph of first stage quiescent current versus adjustable control source current for an RF PA;

FIG. 6 is an example graph of second stage quiescent current versus adjustable control source current for an RF PA;

FIG. 7 illustrates an example graph of proportional to absolute temperature (PTAT) control current for an ideal PTAT control current source;

FIG. 8 illustrates an example graph of a comparison of first stage quiescent current with a PTAT current source;

FIG. 9 is an example graph of second stage quiescent current versus temperature for an RF PA with a PTAT current source;

FIG. 10 illustrates an example communication system according to example embodiments described herein;

FIGS. 11A and 11B illustrate example devices that may implement the teachings according to this disclosure; and

FIG. 12 is a block diagram of a computing system that may be used for implementing the devices disclosed herein.

### DETAILED DESCRIPTION OF ILLUSTRATIVE EMBODIMENTS

The making and using of the disclosed embodiments are discussed in detail below. It should be appreciated, however, that the present disclosure provides many applicable concepts that can be embodied in a wide variety of specific contexts. The specific embodiments discussed are merely illustrative of specific ways to make and use the embodiments, and do not limit the scope of the disclosure.

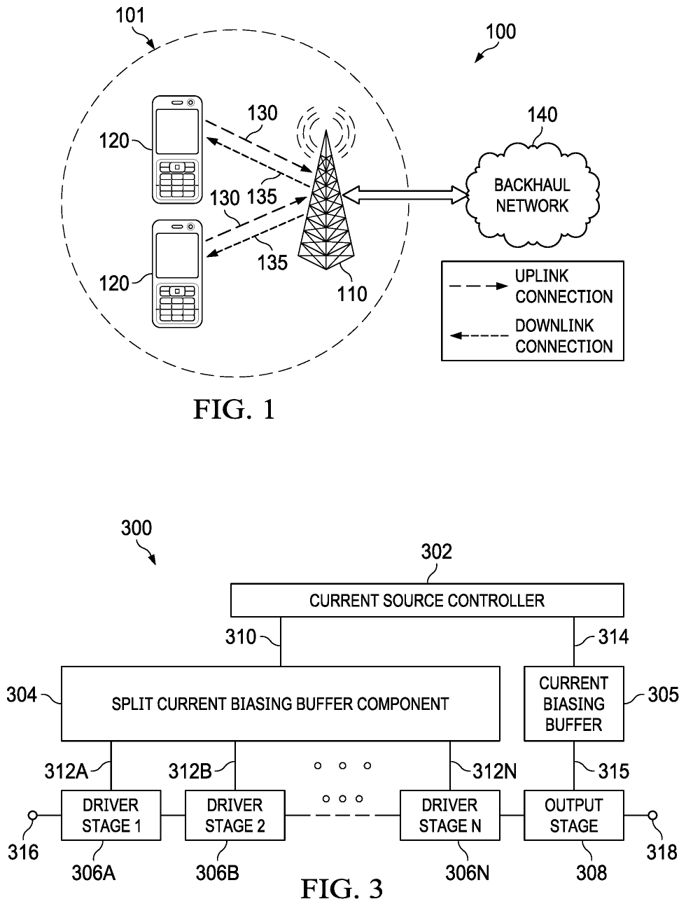

FIG. 1 illustrates an example wireless communications system 100. Communications system 100 includes an access node 110 serving a user equipment (UE) 120 within a coverage area 101. In a first operating mode, communications to and from UE 120, using an uplink connection 130 and a downlink connection 135, respectively, pass through access node 110. In a second operating mode, communications to and from UE 120 do not pass through access node 110, however, access node 110 typically allocates resources used by UE 120 to communicate. Access nodes may also be commonly referred to as Node Bs, evolved Node Bs (eNBs), next generation (NG) Node Bs (gNBs), master eNBs (MeNBs), secondary eNBs (SeNBs), master gNBs (MgNBs), secondary gNBs (SgNBs), network controllers, control nodes, base stations, access points, transmission points (TPs), transmission-reception points (TRPs), cells, carriers, macro cells, femtocells, pico cells, and so on, while UEs may also be commonly referred to as mobile stations, mobiles, terminals, users, subscribers, stations, and the like. Access nodes may provide wireless access in accordance with one or more wireless communication protocols, e.g., the Third Generation Partnership Project (3GPP) long term evolution (LTE), LTE advanced (LTE-A), 5G, 5G LTE, 5G New Radio (NR), High Speed Packet Access (HSPA), Wi-Fi 802.11a/b/g/n/ac/ad/ax/ay, etc. The access node 110 may be in communication with a backhaul network 140. While it is understood that communications systems may employ multiple eNBs capable of communicating with a number of UEs, only one eNB and one UE are illustrated for simplicity.

As discussed above, a radio frequency (RF) power amplifier (PA) front end module is a critical component of the UE. RF PA designs having three or more stages are increasingly desired to operate with the latest generation of digital communication technologies to handle high power out requirements and potential high frequency loss.

With the use of three or more stages in power amplifier design, one of the dilemmas faced by a designer to how to bias driver stages with a minimal amount of current sources that are available from a current controller while still allowing the use of multiple current sources for other uses such as providing smart control features or providing for a thermal adjustable reference device. Accordingly, there is a need for a RF PA in which the limited available external sources provided from a bias controller are able to bias multiple stages of the RF PA.

Traditional designs for a multistage RF PA typically use either multiple separate current sources for biasing each individual stage of the RFPA or use direct resistive split biasing in which resistors split the current source to each of the driver stages. However, such designs have a significant drawback in that they do not provide a smooth variable biasing or linear operation, making them unsuitable for a linear amplifier working, for example, with proportional to absolute temperature (PTAT) current control in which current is proportional to temperature.

One or more embodiments provide a biasing component including separate emitter followers as current buffers that allows use of a single external current source to bias two or more driver stages in an RF PA. One or more embodiments provide for flexibility to allow limited available current sources for other innovative control of the amplifier, such as a configurable output array or adjustable thermal control for a reference device. Additionally, the configuration of one or more embodiments allows a single PTAT current source to provide temperature compensation with two driver stages at the same time to offer greater compensation if desired. In one or more embodiments, by reducing the number of external adjustable current sources required, input/output (IO) structures of a semiconductor die can be simplified, and layout restriction and die size can be improved.

In an embodiment, one or more of the UEs 120 and/or access node 110 may include an RF PA having a biasing component including separate emitter followers as current buffers that allows use of a single external current source to bias two or more driver stages in an RF PA as further described herein with respect to one or more embodiments.

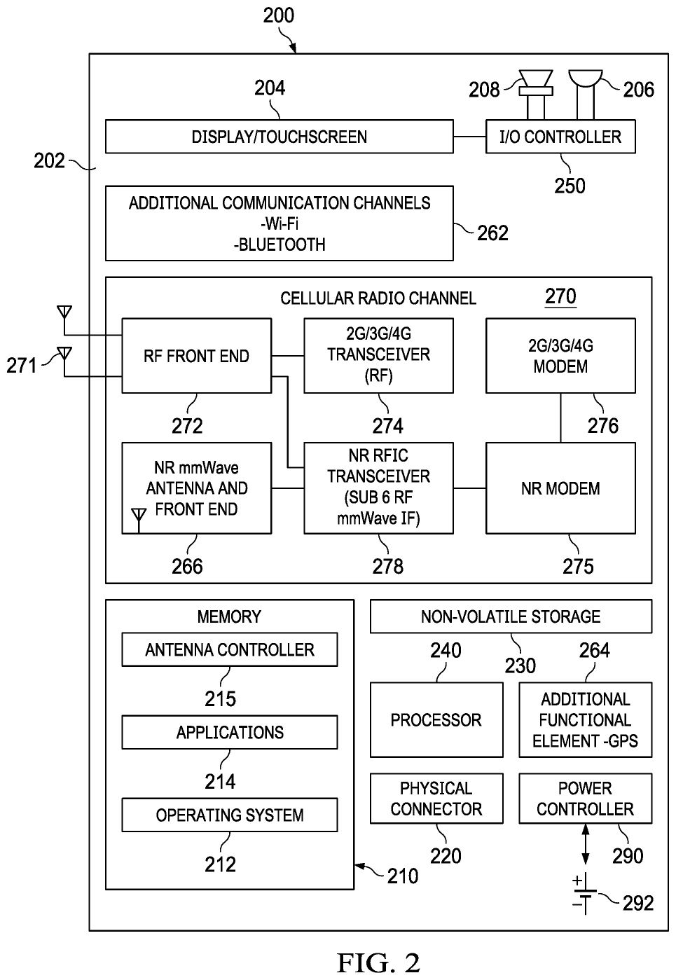

FIG. 2 illustrates an example of architecture for a UE 200 in which the biasing component may be utilized. In a particular embodiment, the UE 200 is a 5G NR mobile processing device. The UE 200 has memory 210, a physical connector 220, processor 240, an input/output (I/O) controller 250, a cellular radio channel 270, and a power controller 290. Each of these components is connected through one or more system buses (not shown).

Memory 210, coupled to processor 240, includes the UE's operating system 212, applications 214, and an antenna controller 215. Memory 2210 can be any variety of memory storage media types, including non-volatile and volatile memory. The operating system 212 handles the different operations of the UE 200 and may contain user interfaces for operations, such as placing and receiving phone calls, text messaging, checking voicemail, and the like. The applications 214 can be any assortment of programs, such as a camera application for photos and/or videos, an address book application, a calendar application, a media player, an internet browser, games, and the like.

The operating system 212 manages the hardware of the UE 200, including hardware such as a display/touchscreen 240, a speaker 208, and a microphone 206. The operating system 212 also manages software (i.e. applications 214) on the UE 200 for performing tasks requested by the user and handling incoming data. This occurs through the operating system's control and allocation memory (i.e. RAM), system tasks, system resources, files systems, and the like. The processor 240 executes operations for the mobile processing device according to this control and allocation.

The power controller 290 of the UE 200 allocates power from the UE's power supply 292 to the circuitry for different mobile processing device components used to operate the UE 200 and its different features. Additionally, the physical connector 220 can be used to connect the UE 200 to an external power source, such as an AC adapter or powered docking station.

The cellular radio channel 270 is used for receiving and transmitting data, such as phone calls, text messages, email, webpage data, and the like. Cellular radio communication can occur through any of the standard network protocols of UE communication (i.e. GSM, PCS, D-AMPS, UMTS, CDMA, WCDMA, LTE, and the like.). The UE 200 may also contain additional communication channels 262, such as Wi-Fi, Bluetooth, and the like, for receiving and transmitting data as well. The UE 200 may have additional functional elements for communication 264, such as GPS. Each of the described communication mediums is accessed via a mmWave and antenna front-end 266 or an RF front end 272 with antenna 271 on the UE 200. The communication mediums for operations of the UE 200 are not limited to the mediums described and can include any other communication mediums known in the art.

The cellular radio channel 270 is illustrated herein as a combination of legacy 2G/3G/4G subsystem and a 5G communication subsystem. It comprises a 2G/3G/4G modem 276, a 2G/3G/4G transceiver 274 (which may be embodied in an LTE RF integrated circuit (RFIC)) coupled to modem 276 and a sub-6 GHz RF front end 272. The 5G subsystem includes a NR modem 275 and a NR transceiver 278 coupled to NR modem 275 and antenna and front-end 266. The 2G/3G/4G subsystem provides communication services for compatibility with legacy systems.

A NR modem 275 provides and receives data in digital baseband via an NR transceiver 278. The digital baseband is provided to the NR Modem 275 by the processor 240 and processed for transmission through the mmWave and antenna front-end 266. Similarly, data is received by the mmWave and antenna front-end 266 and provided to the transceiver for conversion to baseband by the NR modem 275. NR modem 275 and 2G/3G/4G modem 276 share a connection to allow data to be provided through either channel if connectivity to NR frequencies is lost. The NR transceiver 278 transmits and receives data using either mmWave frequencies or legacy sub-6 GHz frequencies, or both, and is therefore connected to both the sub-6 GHz RF front end 272 and the mmWave and antenna front-end 266. In some implementations, 2G/3G/4G transceiver 274 and NR transceiver 278 can be physically combined into single chip or module, while 2G/3G/4G modem 276 and NR modem 275 can be physically combined into single chip or module.

The NR mmWave and antenna front-end 266 may include fixed beam antennas, phased array antennas or hybrid antenna arrays as described herein. Each front-end 266 may comprise one or multiple front-end modules (FEMs). Each module may include one or more steering beam phased array antennas, hybrid antenna arrays and one or more fixed beam antennas. In embodiments, the RF front end 266 and/or the mmWave and antenna front-end 266 include a biasing component including separate emitter followers as current buffers that allows use of a single external current source to bias two or more driver stages in an RF PA as further described herein.

It should be recognized that any suitable processing device, mobile or otherwise, may implement the RF PA biasing component including separate emitter followers as current buffers that allows use of a single external current source to bias two or more driver stages in an RF PA described herein. Hence, although FIG. 2 illustrates a UE, similar components to those illustrated in FIG. 2 may be provided in a communication device or a general-purpose processing device such as a desktop computer, laptop computer, or server.

FIG. 3 illustrates a first example of a radio frequency (RF) power amplifier (PA) 300 having a biasing component to bias two or more driver stages in the RF PA using a single current source. The RF PA 300 includes a current source controller 302, a split current biasing buffer component 304, a current biasing buffer 305, a number of driver stages 306A-306N, and an output stage 308. The current source controller 302 is configured to provide a current source 310 to split current biasing buffer component 304. The split current biasing buffer component 304 is configured to provide a bias voltage 312A-312N for each respective driver stage 306A-306N based upon the single current source 310, and provide the respective bias voltages 312A-312N to the corresponding driver stage 306A-306N. In at least one embodiment, the split current biasing buffer component 304 includes an emitter follower circuit associated with each driver stage 306A-306N for providing the respective biasing voltage 312A-312N to the driver stage 306A-306N. The first driver stage 306A, the second driver stage 306B, and the n-th driver stage 306N each include at least one power amplification device such as a semiconductor device. In a particular embodiment, the semiconductor device includes a transistor device.

In the example illustrated in FIG. 3, the split current biasing buffer component 304 provides a first bias voltage 312A to the first driver stage 306A, a second bias voltage 312B to the second driver stage 306B, and an n-th bias voltage 312N to the n-th driver stage 306N. The current source controller 302 is further configured to provide a second current source 314 to the current biasing buffer 305, and the current biasing buffer 305 is configured to provide a bias voltage 315 to output stage 308. During operation of the RF PA 300, an input signal to be amplified by the RF PA 300 is provided to an input 316 of the first driver stage 306A, and each of driver stages 306A-306N successively amplifies the input signal and provides the amplified signal to output stage 308. Output stage 308 then further amplifies the signal to produce an amplified output signal at an output 318.

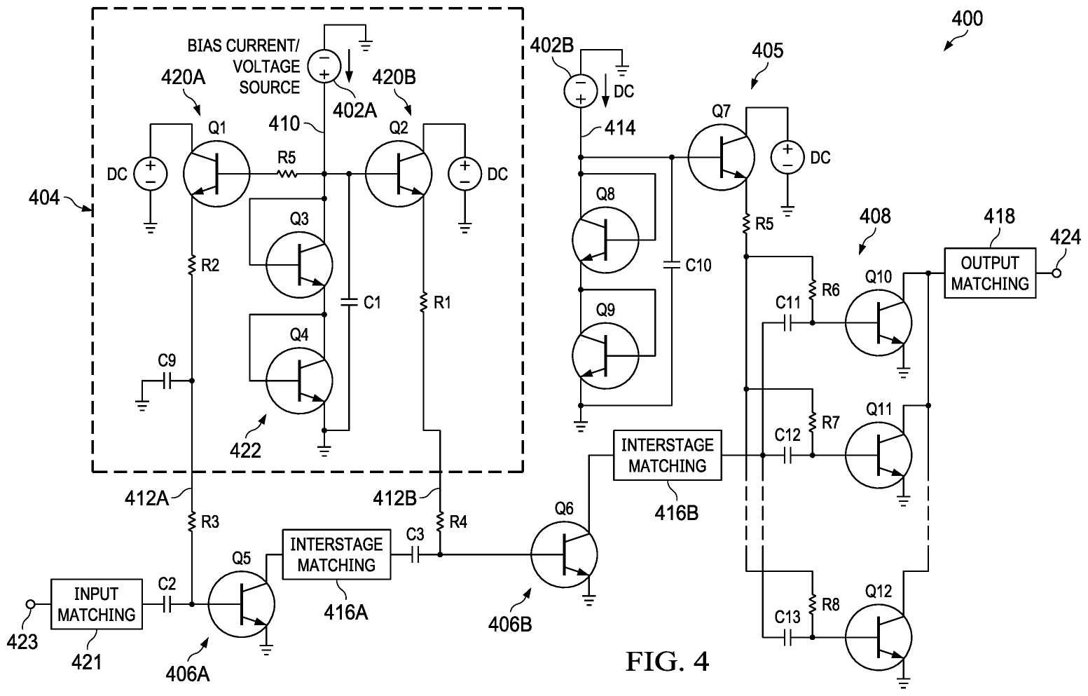

FIG. 4 illustrates a second example of a RF PA 400 having a biasing component to bias two or more driver stages in the RF PA using a single current source. In the embodiment of FIG. 4, the RF PA 400 includes a number of transistor semiconductor devices. The RF PA 400 includes a first controllable current source 402A configured to provide a first source current 410 to a split biasing buffer component 404, and a second controllable current source 402B configured to provide a second source current 414 to the split biasing buffer component 404. The split current biasing buffer component 404 is configured to provide a first bias voltage 412A to a first driver stage 406A and a second bias voltage 412B to a second driver stage 406B of the RF PA 400. The RF PA 400 further includes a current biasing buffer component 405 configured to receive a second source current 414 from a second current source 402B, and provide an output stage bias voltage to an output stage 408.

The RF PA 400 further includes a first interstage matching component 416A, a second interstage matching component 416B, an output matching component 418, and an input matching component 421. The input matching component 421 is configured to match impedance between an input 423 and the first driver stage 406a. The first interstage matching component 416A is configured to match impedance between the first driver stage 406A and the second driver stage 406B. The second interstage matching component 416B is configured to match impedance between the second driver stage 406B and the output stage 408. The output matching component 418 is configured to match impedance between the output stage 408 and an output 424.

During operation of the RF PA 400, an input signal to be amplified by the RF PA 400 is provided to the input 421 of the input matching component 421, and each of the first driver stage 406A second driver stage 406B successively amplifies the input signal and provides the amplified signal to output stage 408. The output stage 408 then further amplifies the signal to produce an amplified output signal at the output 424.

The split current biasing buffer component 404 includes a first emitter follower circuit 420A, a second emitter follower circuit 420B, and a diode circuit 422. The first emitter follower circuit 420A includes a first transistor Q1 having a base coupled to the first controllable current source 402A via a resistor R5, a collector coupled to a DC voltage source, and an emitter coupled to the first driver stage 406A and a capacitor C9 via a resistor R2. The second emitter follower circuit 420B includes a second transistor Q2 having a base coupled to the first controllable current source 402A, a collector coupled to a DC voltage source, and an emitter coupled to the second driver stage 406B via a resistor R1. In particular embodiments, transistors Q2 and Q1 may be connected to either the same or a different DC voltage source. In some embodiments, resistors R1 and R2 may include any resistive element.

The diode circuit 422 includes a pair of transistors Q3 and Q4 coupled between the first controllable current source 402A and a ground, and a capacitor C1 coupled in parallel with transistor Q3 and transistor Q4. In the particular embodiment illustrated in FIG. 4, the diode circuit 422 includes bipolar junction transistors (BJTs) Q3 and Q4 connected in a diode configuration. The source current 410 is injected into the diode circuit 422 to form a bias voltage at the common node where the split connected emitter followers 420A 420B branch out from the common node to feed bias voltages to each of the first driver stage 406A formed by transistor Q5 and second driver stage 406B formed by transistor Q6.

The first emitter follower circuit 420A is configured to provide a first bias voltage 412A to the first driver stage 406A based on the first source current 410. The second emitter follower circuit 420B is configured to provide a second bias voltage 412B to the second driver stage 406B. In particular embodiments, the amount of voltage of the first bias voltage 412A and the second bias voltage 412B is adjustable according the respective resistance values of resistor R2 and R1. In particular embodiments, a ratio of the first bias voltage 412A to the second bias voltage 412B is adjustable based upon a ratio of the resistance value of R2 and a resistance value of R1. In a particular embodiment, the ratio of the first bias voltage 412A to the second bias voltage 412B is further adjustable based upon a ratio of an emitter size of the first emitter follower 420A to an emitter size of the second emitter follower 420B.

The current biasing buffer 405 includes a plurality of transistors Q7, Q8, and Q9 configured to receive the second source current 414 from the second current source 402B and provide the output stage bias voltage via a resistor R5 to the output stage 408. The output stage 408 includes a plurality of output stage transistors Q10, Q11, . . . , Q12 arranged in parallel. A base of each of the output stage transistors Q10, Q11, Q12 is coupled to the second interstage matching component 416B via a respective capacitor C11, C12, and C13, and receives the output stage bias voltage through respective resistors R6, R7, and R8. A collector of each of the output stage transistors Q10, Q11, Q12 is coupled to the output matching component 418, and an emitter of each of the output stage transistors Q10, Q11, Q12 is coupled to ground.

The first driver stage 406A includes a transistor Q5 having a base configured to receive the first bias voltage 412A via a resistor R3, and a collector coupled to the first interstage matching component 416A. The base of the transistor Q5 is further coupled to the input matching component 421 via a capacitor C2. An emitter of transistor Q5 is coupled to ground. The second driver stage 406B includes a transistor Q6 having a base configured to receive the second bias voltage 412B via a resistor R4, and a collector coupled to the second interstage matching component 416B. The base of the transistor Q6 is further coupled to the first interstage matching component 416A via a capacitor C3. An emitter of transistor Q6 is coupled to ground.

Accordingly, the separate emitter follower circuits 420A and 420B of split current biasing buffer component 404 operate as current buffers that allow use of a single external current source to bias driver stages 406A-406B in the RF PA 400.

Although the particular embodiment illustrated in FIG. 4 shows the split current biasing buffer component 404 as including the first emitter follower circuit 420A and the second emitter follower circuit 420B being used to provide separate bias voltages 412A-412B from a single source current 410 to the first driver stage 406A and the second driver stage 406B, respectively, it should be understood that in other embodiments, the split current biasing buffer component 404 may include any number of emitter follower circuits to provide separate bias voltages to any number of stages of the RF PA.

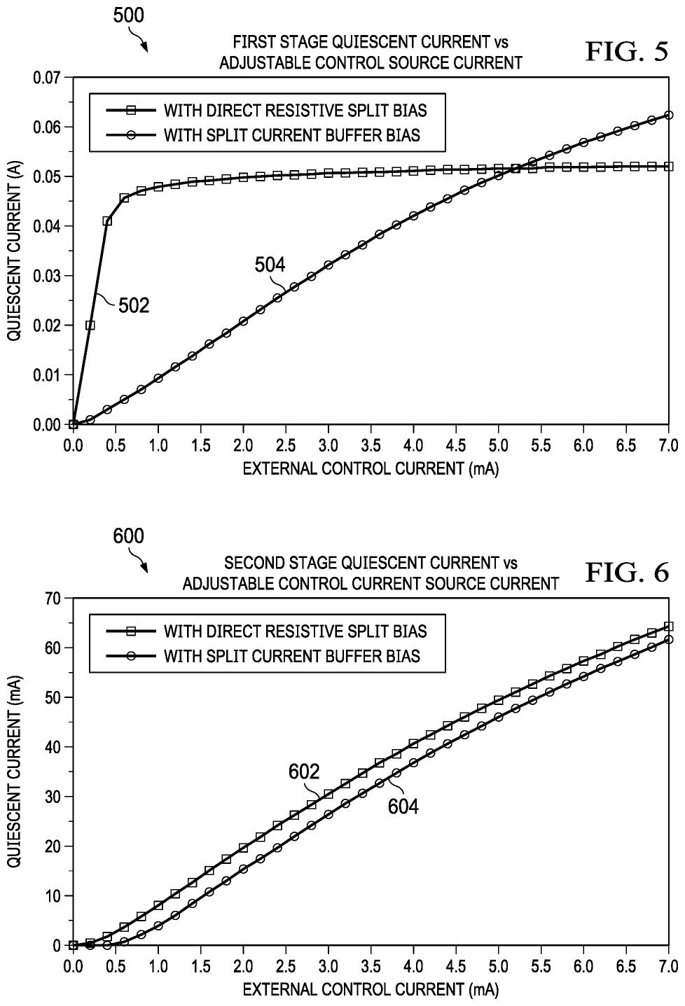

FIG. 5 is an example graph 500 of first stage quiescent current versus adjustable control source current for an RF PA. A y-axis of graph 500 indicates quiescent current of the first stage of a RF PA, and an x-axis of graph 500 indicates an external control current. Quiescent current refers to the current of the RF PA when it is not fed with an RF signal at its input. FIG. 5 includes a plot 502 of first stage quiescent current versus external control current for a RF PA having a traditional direct resistive split bias. Plot 502 illustrates an example in which the quiescent current versus external control current remains substantially flat beyond approximately 0.5 milliamps (mA) of external control current for a resistive split bias. FIG. 5 further includes a plot 504 of first stage quiescent current versus external control current for a RF PA having a split current buffer bias as described herein with respect to one or more embodiments. In contrast to the resistive split bias behavior, plot 504 shows that the quiescent current versus external control current varies in a constant substantially linear manner for split current buffer bias as described with respect to various embodiments herein.

FIG. 6 is an example graph 600 of second stage quiescent current versus adjustable control source current for an RF PA. A y-axis of graph 600 indicates quiescent current of a RF PA, and an x-axis of graph 600 indicates an external control current. FIG. 6 includes a plot 602 of second stage quiescent current versus external control current for a RF PA having a traditional direct resistive split bias. FIG. 6 further includes a plot 604 of second stage quiescent current versus external control current for a RF PA having a split current buffer bias as described herein with respect to one or more embodiments. FIG. 6 illustrates that the second stage quiescent current vs adjustable control source current for both direct resistive split bias and split current bias are similar.

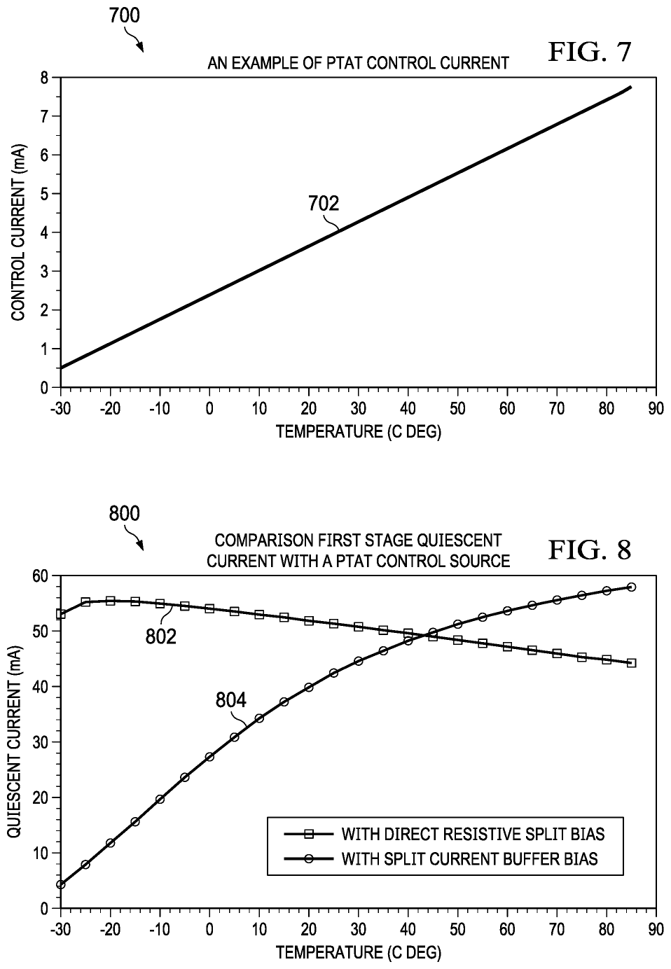

FIG. 7 illustrates an example graph 700 of proportional to absolute temperature (PTAT) control current for an ideal PTAT control current source. A y-axis of graph 700 indicates control current of a RF PA, and an x-axis of graph 600 indicates temperature in degrees C. A plot 702 illustrates that the control current is proportional to temperature for a PTAT control current source in an ideal case.

FIG. 8 illustrates an example graph 800 of a comparison of first stage quiescent current with a PTAT current source. A y-axis of graph 800 indicates a first stage quiescent current of a RF PA, and an x-axis of graph 800 indicates temperature in degrees C. FIG. 8 includes a plot 802 of first stage quiescent current versus temperature for a RF PA having a traditional direct resistive split bias. FIG. 8 further includes a plot 804 of first stage quiescent current versus temperature for a RF PA having a split current buffer bias as described herein with respect to one or more embodiments. As shown in FIG. 8, the first stage quiescent current for a RF PA having a split current buffer bias is much closer to that of the ideal case illustrated in FIG. 7 than that of the direct resistive split bias case.

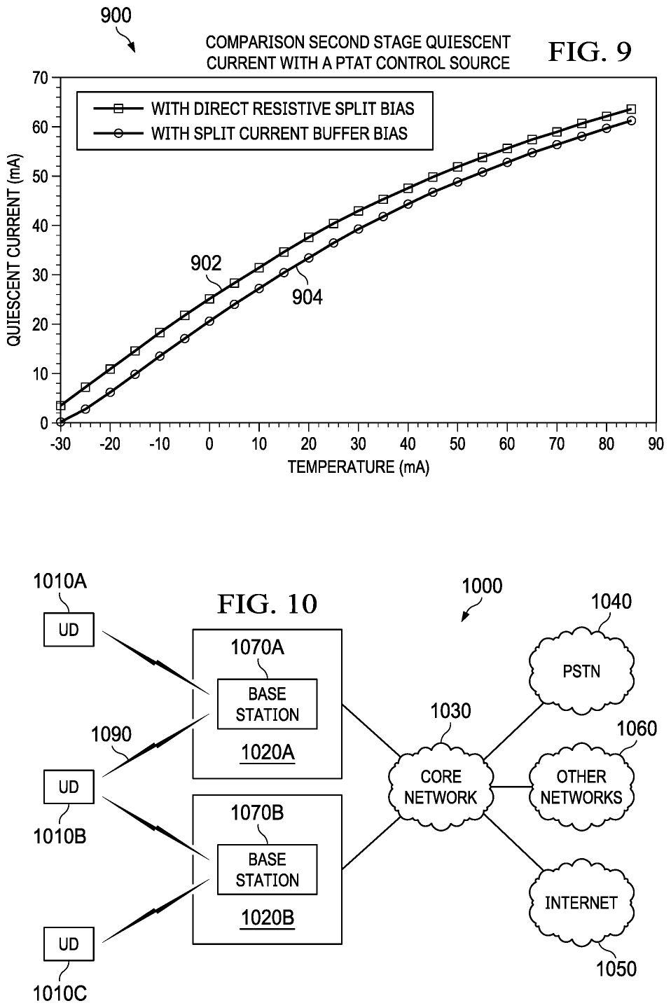

FIG. 9 is an example graph 900 of second stage quiescent current versus temperature for an RF PA with a PTAT current source. A y-axis of graph 900 indicates a second stage quiescent current of a RF PA, and an x-axis of graph 900 indicates temperature in degrees C. FIG. 9 includes a plot 902 of second stage quiescent current versus temperature for a RF PA having a traditional direct resistive split bias. FIG. 9 further includes a plot 904 of second stage quiescent current versus temperature for a RF PA having a split current buffer bias as described herein with respect to one or more embodiments. FIG. 9 illustrates that the second stage quiescent current versus temperature for both direct resistive split bias and split current bias are similar.

FIGS. 5-9 illustrate that a bias scheme using direct resistor biasing for the first stage does not provide effective temperature compensation that should result in a rising quiescent current under a PTAT control current source. In contrast, split current buffer bias as described herein with respect to one or more embodiments provides for effective temperature compensation that results in a desired rising quiescent current under a PTAT control current source.

FIG. 10 illustrates an example communication system 1000. In general, the system 1000 enables multiple wireless or wired users to transmit and receive data and other content. The system 1000 may implement one or more channel access methods, such as code division multiple access (CDMA), time division multiple access (TDMA), frequency division multiple access (FDMA), orthogonal FDMA (OFDMA), single-carrier FDMA (SC-FDMA), or non-orthogonal multiple access (NOMA).

In this example, the communication system 1000 includes user devices (UD) 1010a-1010c, radio access networks (RANs) 1020a-1020b, a core network 1030, a public switched telephone network (PSTN) 1040, the Internet 1050, and other networks 1060. While certain numbers of these components or elements are shown in FIG. 10, any number of these components or elements may be included in the system 1000.

The UDs 1010a-1010c are configured to operate or communicate in the system 1000. For example, the UDs 1010a-1010c are configured to transmit or receive via wireless or wired communication channels. Each UD 1010a-1010c represents any suitable end user device and may include such devices (or may be referred to) as a user equipment or device (UE), wireless transmit or receive unit (WTRU), mobile station, fixed or mobile subscriber unit, cellular telephone, personal digital assistant (PDA), smartphone, laptop, computer, touchpad, wireless sensor, or consumer electronics device. Each UD 1010a-1010c may include a transceiver having a biasing component including separate emitter followers as current buffers that allows use of a single external current source to bias two or more driver stages in an RF PA as described herein with respect to one or more embodiments.

The RANs 1020a-1020b here include base stations 1070a-1070b, respectively. Each base station 1070a-1070b is configured to wirelessly interface with one or more of the UDs 1010a-1010c to enable access to the core network 1030, the PSTN 1040, the Internet 1050, or the other networks 1060. For example, the base stations 1070a-1070b may include (or be) one or more of several well-known devices, such as a base transceiver station (BTS), a Node-B (NodeB), an evolved NodeB (eNodeB), a Next Generation (NG) NodeB (gNB), a Home NodeB, a Home eNodeB, a site controller, an access point (AP), or a wireless router. The base stations 1070a-1070b may each include a transceiver having an RF PA with a biasing component including separate emitter followers as current buffers that allows use of a single current source to bias two or more driver stages in the RF PA as further described herein with respect to one or more embodiments. The UDs 1010a-1010c are configured to interface and communicate with the Internet 1050 and may access the core network 1030, the PSTN 1040, or the other networks 1060.

In the embodiment shown in FIG. 10, the base station 1070a forms part of the RAN 1020a, which may include other base stations, elements, or devices. Also, the base station 1070b forms part of the RAN 1020b, which may include other base stations, elements, or devices. Each base station 1070a-1070b operates to transmit or receive wireless signals within a particular geographic region or area, sometimes referred to as a “cell.” In some embodiments, multiple-input multiple-output (MIMO) technology may be employed having multiple transceivers for each cell.

The base stations 1070a-1070b communicate with one or more of the UDs 1010a-1010c over one or more air interfaces 1090 using wireless communication links. The air interfaces 1090 may utilize any suitable radio access technology.

It is contemplated that the system 1000 may use multiple channel access functionality, including such schemes as described above. In particular embodiments, the base stations and UDs implement 5G New Radio (NR), LTE, LTE-A, or LTE-B. Of course, other multiple access schemes and wireless protocols may be utilized.

The RANs 1020a-1020b are in communication with the core network 1030 to provide the UDs 1010a-1010c with voice, data, application, Voice over Internet Protocol (VoIP), or other services. Understandably, the RANs 1020a-1020b or the core network 1030 may be in direct or indirect communication with one or more other RANs (not shown). The core network 1030 may also serve as a gateway access for other networks (such as the PSTN 1040, the Internet 1050, and the other networks 1060). In addition, some or all of the UDs 1010a-1010c may include functionality for communicating with different wireless networks over different wireless links using different wireless technologies or protocols. Instead of wireless communication (or in addition thereto), the UDs may communicate via wired communication channels to a service provider or switch (not shown), and to the Internet 1050.

Although FIG. 10 illustrates one example of a communication system, various changes may be made to FIG. 10. For example, the communication system 1000 could include any number of UDs, base stations, networks, or other components in any suitable configuration.

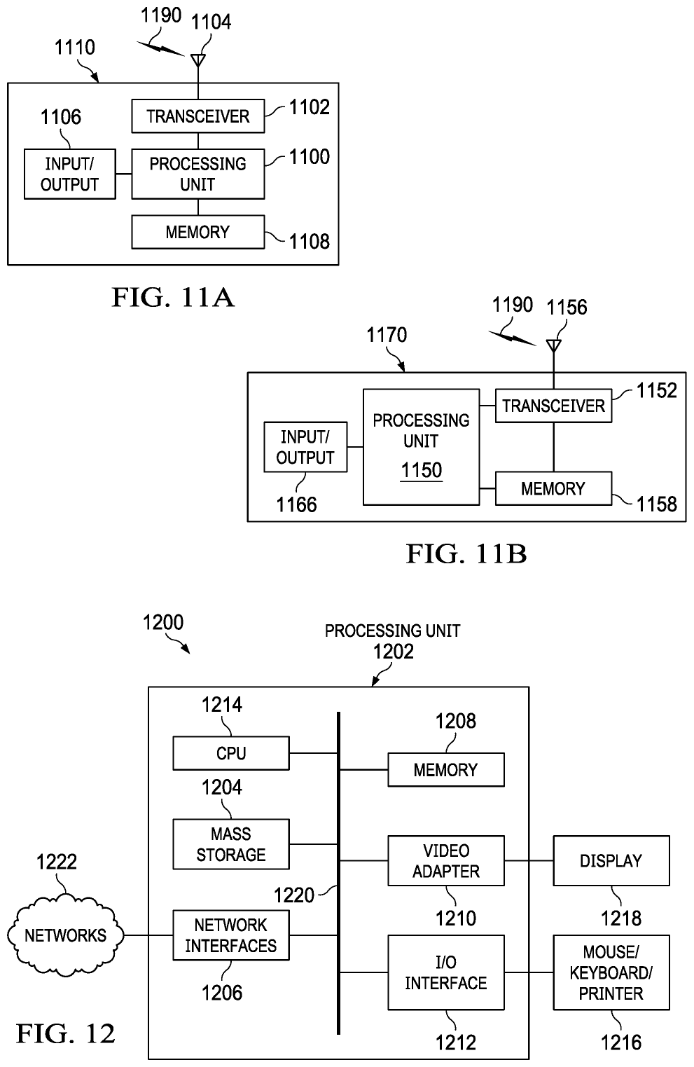

FIGS. 11A and 11B illustrate example devices that may implement the methods and teachings according to this disclosure. In particular, FIG. 11A illustrates an example UD 1110, and FIG. 11B illustrates an example base station 1170. These components could be used in the system 1000 or in any other suitable system.

As shown in FIG. 11A, the UD 1110 includes at least one processing unit 1100. The processing unit 1100 implements various processing operations of the UD 1110. For example, the processing unit 1100 could perform signal coding, data processing, power control, input/output processing, or any other functionality enabling the UD 1110 to operate in the system 1000. The processing unit 1100 also supports the methods and teachings described in more detail above. Each processing unit 1100 includes any suitable processing or computing device configured to perform one or more operations. Each processing unit 1100 could, for example, include a microprocessor, microcontroller, digital signal processor, field programmable gate array, or application specific integrated circuit.

The UD 1110 also includes at least one transceiver 1102. The transceiver 1102 is configured to modulate data or other content for transmission by at least one antenna or NIC (Network Interface Controller) 1104. The transceiver 1102 is also configured to demodulate data or other content received by the at least one antenna 1104. Each transceiver 1102 includes any suitable structure for generating signals for wireless or wired transmission or processing signals received wirelessly or by wire. Each transceiver 1102 may include an RF PA with a biasing component including separate emitter followers as current buffers that allows use of a single current source to bias two or more driver stages in the RF PA as further described herein with respect to one or more embodiments. Each antenna 1104 includes any suitable structure for transmitting or receiving wireless or wired signals. One or multiple transceivers 1102 could be used in the UD 1110, and one or multiple antennas 1104 could be used in the UD 1110. Although shown as a single functional unit, a transceiver 1102 could also be implemented using at least one transmitter and at least one separate receiver.

The UD 1110 further includes one or more input/output devices 1106 or interfaces (such as a wired interface to the Internet 1050). The input/output devices 1106 facilitate interaction with a user or other devices (network communications) in the network. Each input/output device 1106 includes any suitable structure for providing information to or receiving information from a user, such as a speaker, microphone, keypad, keyboard, display, or touch screen, including network interface communications.

In addition, the UD 1110 includes at least one memory 1108. The memory 1108 stores instructions and data used, generated, or collected by the UD 1110. For example, the memory 1108 could store software or firmware instructions executed by the processing unit(s) 1100 and data used to reduce or eliminate interference in incoming signals. Each memory 1108 includes any suitable volatile or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, and the like.

As shown in FIG. 11B, the base station 1170 includes at least one processing unit 1150, at least one transceiver 1152, which includes functionality for a transmitter and a receiver, one or more antennas 1156, at least one memory 1158, and one or more input/output devices or interfaces 1166. A scheduler, which would be understood by one skilled in the art, is coupled to the processing unit 1150. The scheduler could be included within or operated separately from the base station 1170. The processing unit 1150 implements various processing operations of the base station 1170, such as signal coding, data processing, power control, input/output processing, or any other functionality. The processing unit 1150 can also support the methods and teachings described in more detail above. Each processing unit 1150 includes any suitable processing or computing device configured to perform one or more operations. Each processing unit 1150 could, for example, include a microprocessor, microcontroller, digital signal processor, field programmable gate array, or application specific integrated circuit.

Each transceiver 1152 includes any suitable structure for generating signals for wireless or wired transmission to one or more UDs or other devices. Each transceiver 1152 further includes any suitable structure for processing signals received wirelessly or by wire from one or more UDs or other devices. Each transceiver 1152 may include an RF PA with a biasing component including separate emitter followers as current buffers that allows use of a single current source to bias two or more driver stages in the RF PA as further described herein with respect to one or more embodiments. Although shown combined as a transceiver 1152, a transmitter and a receiver could be separate components. Each antenna 1156 includes any suitable structure for transmitting or receiving wireless or wired signals. While a common antenna 1156 is shown here as being coupled to the transceiver 1152, one or more antennas 1156 could be coupled to the transceiver(s) 1152, allowing separate antennas 1156 to be coupled to the transmitter and the receiver if equipped as separate components. Each memory 1158 includes any suitable volatile or non-volatile storage and retrieval device(s). Each input/output device 1166 facilitates interaction with a user or other devices (network communications) in the network. Each input/output device 1166 includes any suitable structure for providing information to or receiving/providing information from a user, including network interface communications.

FIG. 12 is a block diagram of a computing system 1200 that may be used for implementing the devices and methods disclosed herein. For example, the computing system can be any entity of UE, access network (AN), mobility management (MM), session management (SM), user plane gateway (UPGW), or access stratum (AS). Specific devices may utilize all of the components shown or only a subset of the components, and levels of integration may vary from device to device. Furthermore, a device may contain multiple instances of a component, such as multiple processing units, processors, memories, transmitters, receivers, etc. The computing system 1200 includes a processing unit 1202. The processing unit includes a central processing unit (CPU) 1214, memory 1208, and may further include a mass storage device 1204, a video adapter 1210, and an I/O interface 1212 connected to a bus 1220.

The bus 1220 may be one or more of any type of several bus architectures including a memory bus or memory controller, a peripheral bus, or a video bus. The CPU 1214 may comprise any type of electronic data processor. The memory 1208 may comprise any type of non-transitory system memory such as static random access memory (SRAM), dynamic random access memory (DRAM), synchronous DRAM (SDRAM), read-only memory (ROM), or a combination thereof. In an embodiment, the memory 1208 may include ROM for use at boot-up, and DRAM for program and data storage for use while executing programs.

The mass storage 1204 may comprise any type of non-transitory storage device configured to store data, programs, and other information and to make the data, programs, and other information accessible via the bus 1220. The mass storage 1204 may comprise, for example, one or more of a solid state drive, hard disk drive, a magnetic disk drive, or an optical disk drive.

The video adapter 1210 and the I/O interface 1212 provide interfaces to couple external input and output devices to the processing unit 1202. As illustrated, examples of input and output devices include a display 1218 coupled to the video adapter 1210 and a mouse, keyboard, or printer 1216 coupled to the I/O interface 1212. Other devices may be coupled to the processing unit 1202, and additional or fewer interface cards may be utilized. For example, a serial interface such as Universal Serial Bus (USB) (not shown) may be used to provide an interface for an external device.

The processing unit 1202 also includes one or more network interfaces 1206, which may comprise wired links, such as an Ethernet cable, or wireless links to access nodes or different networks. The network interfaces 1206 allow the processing unit 1202 to communicate with remote units via the networks. For example, the network interfaces 1206 may provide wireless communication via one or more transmitters/transmit antennas and one or more receivers/receive antennas. In an embodiment, the processing unit 1202 is coupled to a local-area network 1222 or a wide-area network for data processing and communications with remote devices, such as other processing units, the Internet, or remote storage facilities.

It should be appreciated that one or more steps of the embodiment methods provided herein may be performed by corresponding units or modules. For example, a signal may be transmitted by a transmitting unit or a transmitting module. A signal may be received by a receiving unit or a receiving module. A signal may be processed by a processing unit or a processing module. The respective units or modules may be hardware, software, or a combination thereof. For instance, one or more of the units or modules may be an integrated circuit, such as field programmable gate arrays (FPGAs) or application-specific integrated circuits (ASICs).

One or more embodiments described herein may provide for a single current source from a bias controller to provide bias for multiple driver stages in an RF PA. One or more embodiments may provide flexibility to allow limited available current sources to be used for other innovative control of the amplifier such as providing for a configurable output array or adjustable thermal control for a reference device. In one or more embodiments, by reducing the number of external adjustable current sources, chip I/O can be simplified, and layout restrictions and die sizes may be improved. One or more embodiments described may be applicable to a large number of RF power amplifier designs for wireless applications in which linearity is desired for such technologies as WCDMA, LTE, 5G, and WiFi.

Although the present disclosure and its advantages have been described in detail, it should be understood that various changes, substitutions and alterations can be made herein without departing from the spirit and scope of the disclosure as defined by the appended claims.

What is claimed is:

1. A power amplifier driver comprising:
a first driver stage;
a second driver stage; and
a biasing component including a first emitter follower circuit and a second emitter follower circuit, the biasing component configured to receive a first source current from a first current source, and to provide a first bias voltage to the first driver stage using the first emitter follower circuit and a second bias voltage to the second driver stage using the second emitter follower circuit, the first bias voltage and the second bias voltage being based upon the first current source.

2. The power amplifier driver of claim 1, wherein the first driver stage includes a first power amplification device and the second driver stage includes a second power amplification device.

3. The power amplifier driver of claim 2, wherein the first bias voltage is provided to the first power amplification device, and the second bias voltage is provided to the second power amplification device.

4. The power amplifier driver of claim 1, further comprising a diode circuit coupled to a common node between the first emitter follower circuit and the second emitter follower circuit, the diode circuit configured to receive the first source current from the first current source.

5. The power amplifier driver of claim 1, wherein the first emitter follower circuit includes a first semiconductor device, and the second emitter follower circuit includes a second semiconductor device.

6. The power amplifier driver of claim 5, wherein a first base of the first semiconductor device is coupled to the first source current, and a second base of the second semiconductor device is coupled to the first source current.

7. The power amplifier driver of claim 5, wherein a first emitter of the first semiconductor device is coupled to the first driver stage, the first emitter providing the first bias voltage to the first driver stage.

8. The power amplifier driver of claim 7, wherein a second emitter of the second semiconductor device is coupled to the second driver stage, the second emitter providing the second bias voltage to the second driver stage.

9. The power amplifier driver of claim 8, wherein the first emitter is coupled to the first driver stage via a first resistive element having a first resistance value, and the second emitter is coupled to the second driver stage via a second resistive element having a second resistance value.

10. The power amplifier driver of claim 9, wherein a first ratio of the first bias voltage to the second bias voltage is adjustable based upon a second ratio of the first resistance value and the second resistance value.

11. The power amplifier driver of claim 10, wherein the first ratio of the first bias voltage to the second bias voltage is further adjustable based upon a third ratio of a first emitter size of the first emitter follower circuit to a second emitter size of the second emitter follower circuit.

12. The power amplifier driver of claim 5, wherein a first collector of the first semiconductor device is coupled to a first voltage source, and a second collector of the second semiconductor device is coupled to a second voltage source.

13. The power amplifier driver of claim 5, wherein a first collector of the first semiconductor device and a second collector of the second semiconductor device are coupled to a same voltage source.

14. The power amplifier driver of claim 1, wherein a first output of the first driver stage is coupled to a first input of the second driver stage.

15. A power amplifier comprising:
a first driver stage;
a second driver stage coupled to the first driver stage;
an output stage coupled to the second driver stage; and
a biasing component including a first emitter follower circuit and a second emitter follower circuit, the biasing component configured to receive a first source current from a first current source, and provide a first bias voltage to the first driver stage using the first emitter follower circuit and a second bias voltage to the second driver stage using the second emitter follower circuit, the first bias voltage and the second bias voltage being based upon the first current source.

16. The power amplifier of claim 15, wherein the output stage is configured to receive a third bias voltage from a second current source.

17. The power amplifier of claim 16, wherein the first current source is different from the second current source.

18. A device comprising:
a transceiver;
a power amplifier coupled to the transceiver, the power amplifier including a first driver stage and a second driver stage;
a first current source; and
a biasing component including a first emitter follower circuit and a second emitter follower circuit, the biasing component configured to receive a first source current from the first current source, and provide a first bias voltage to the first driver stage using the first emitter follower circuit and a second bias voltage to the second driver stage using the second emitter follower circuit based upon the first current source.

19. The device of claim 18, wherein the first driver stage includes a first power amplification device and the second driver stage includes a second power amplification device.

20. The device of claim 19, wherein the first bias voltage is provided to the first power amplification device, and the second bias voltage is provide to the second power amplification device.
